(19) United States
(12) Patent Application Publication
(10) Pub. No.: US 2009/0009163 A1
(43) Pub. Date: Jan. 8, 2009

(54) MAGNETIC SENSING DEVICE AND ELECTRONIC COMPASS USING THE SAME

(75) Inventor: Yukimitsu Yamada, Miaygi-ken (JP)

Correspondence Address: Beyer Law Group LLP, P.O. BOX 1687, Cupertino, CA, 95015-1687, US

(73) Assignee: ALPS ELECTRIC CO., LTD., Tokyo (JP)

(21) Appl. No.: 12/205,549

(22) Filed: Sep. 5, 2008

Related U.S. Application Data
(63) Continuation of application No. PCT/JP2007/053575, filed on Feb. 27, 2007.

(30) Foreign Application Priority Data
Mar. 6, 2006 (JP) 2006-059823

(51) Int. Cl. G01R 33/02

(52) U.S. Cl. 324/244

(57) ABSTRACT

Positive and negative bias magnetic fields are applied to a sensor unit 12 to determine first and second output voltages. A first difference between the first and second output voltages is calculated. Next, correction bias magnetic fields, each of which is obtained by adding an additional bias magnetic field to a corresponding one of the positive and negative bias magnetic fields, are applied to the sensor unit 12 to determine first and second output voltages. A second difference between the first and second output voltages is calculated. Then, the first difference is compared with the second difference. When the first difference is larger than the second difference, the magnitude of the additional bias magnetic field is increased to minimize the difference, i.e., to made the difference substantially zero.

### CLAIM OF PRIORITY

This is a continuation of International Application No. PCT/JP2007/053575, filed Feb. 27, 2007, which is incorporated herein by reference in its entirety.

### BACKGROUND OF THE INVENTION

1. Field of the Invention

The present invention relates to a magnetic sensing device and an electronic compass using the magnetic sensing device.

2. Description of the Related Art

When direction determination is electronically performed, a magnetic sensor for detecting an external magnetic field such as a geomagnetic field is used. When a direction is determined using a magnetic sensing circuit including the magnetic sensor, a technique is known, in which an alternating-current magnetic field is applied to the magnetic sensor, and in which a voltage that is output from the magnetic sensor when the alternating-current magnetic field is applied is used.

In this technique, a magnetic sensor is used, which includes a magnetoresistive element that changes an internal resistance in response to application of a magnetic field. The magnetoresistive element shows a symmetrical change in resistance with respect to a magnetic field as shown in FIG. 2. When an external magnetic field, such as a geomagnetic field, is applied, the resistance is shifted either to the left side or to the right side in a characteristic curve shown in FIG. 2. In this case, the operating point of the magnetoresistive element is present in an inclined region (in a linear region, for example, at a position of Ha) of the characteristic curve. When an alternating-current magnetic field is additionally applied to the magnetoresistive element, a change in resistance can be detected by utilizing the characteristics of the magnetoresistive element. Then, a current is added in a certain direction so that the external magnetic field is cancelled out to move the resistance to the position of a peak shown in FIG. 2, whereby the current corresponding to the external magnetic field can be detected. The intensity of the external magnetic field can be determined using the value of the current.

### SUMMARY OF THE INVENTION

For example, there is a problem that, when an electronic compass in which the above-described magnetic sensing circuit is used is mounted in a mobile phone or the like, it is difficult to accurately detect an external magnetic field because the electronic compass is influenced by magnetic noise (hereinafter, simply referred to as a “leakage magnetic field”) that occurs from an electronic component, such as a speaker, mounted in the mobile phone and that does not include magnetic noise due to a geomagnetic field.

It is an object of the present invention to provide a magnetic sensing device that can accurately detect an external magnetic field even in an environment in which a leakage magnetic field exists, and to provide an electronic compass using the magnetic sensing device.

A magnetic sensing device according to the present invention includes a magnetic sensor for detecting magnetism, bias-magnetic-field generating means for applying bias magnetic fields having opposite polarities to each other to the magnetic sensor, detecting means for detecting output voltages that are obtained in response to the bias magnetic fields having the corresponding polarities, calculating means for determining a difference between the output voltages that are obtained in response to the bias magnetic fields having the corresponding polarities, and control means for controlling the bias-magnetic-field generating means so that the difference becomes substantially zero.

According to the configuration described above, even when a leakage magnetic field acts on the magnetic sensor, a peak of a voltage-versus-magnetic-field characteristic curve of the magnetic sensor can be detected. As a result, even in an environment in which a leakage magnetic field exists, accurate detection of magnetism can be performed. Additionally, a peak is detected by making the difference between the output voltages obtained in a case in which the positive and negative bias magnetic fields are applied substantially zero. Thus, even when a central portion (a peak) of the magnetoresistance characteristics of a magnetoresistive element to be used has broad characteristics or hysteresis characteristics, accurate detection of magnetism can be performed.

In the magnetic sensing device according to the present invention, it is preferable that the bias-magnetic-field generating means apply pairs of bias magnetic fields to the magnetic sensor, the magnitudes of the pairs of bias magnetic fields being different from one another, each of the pairs of bias magnetic fields having opposite polarities. It is preferable that the control means control the bias-magnetic-field generating means so that a difference between output voltages corresponding to each of the pairs of bias magnetic fields becomes substantially zero. According to the configuration, a peak of the magnetoresistance characteristics can be detected with a higher accuracy.

In the magnetic sensing device according to the present invention, it is preferable that the calculating means determine an external magnetic field acting on the magnetic sensor using a first pair of correction magnetic fields and a second pair of correction magnetic fields, the first pair of correction magnetic fields being obtained in a case in which the difference between the output voltages becomes substantially zero when the bias-magnetic-field generating means applies a first pair of bias magnetic fields to the magnetic sensor, the second pair of correction magnetic fields being obtained in a case in which the difference between the output voltages becomes substantially zero when the bias-magnetic-field generating means applies a second pair of bias magnetic fields to the magnetic sensor, the magnitude of the second pair of bias magnetic fields being different from that of the first pair of bias magnetic fields.

In the magnetic sensing device according to the present invention, it is preferable that an approximate line be determined using values of correction magnetic fields having one polarity, each of the correction magnetic fields being included in a corresponding one of the first and second pairs of correction magnetic fields, that an approximate line be determined using values of correction magnetic fields having the other polarity, each of the correction magnetic fields being included in a corresponding one of the first and second pairs of correction magnetic fields, that a magnetic-field-zero point be determined using the approximate lines, and that the external magnetic field be determined using the magnetic-field-zero point and the first or second pair of correction magnetic fields.

In the magnetic sensing device according to the present invention, it is preferable that the magnetic sensor include a magnetoresistive element that shows a symmetrical change in resistance with respect to a magnetic field. In this case, it is preferable that the magnetoresistive element be a GIG element or an MR element.

In the magnetic sensing device according to the present invention, it is preferable that the magnetic sensor be configured as a bridge circuit.

An electronic compass according to the present invention includes the magnetic sensing devices that are described above, and direction-calculating means for determining a direction using voltage differences, each of which is obtained by a corresponding one of the magnetic sensing devices.

According to the configuration described above, even when a leakage magnetic field acts on the magnetic sensors, a peak of a voltage-versus-magnetic-field characteristic curve of the magnetic sensors can be detected. As a result, even in an environment in which a leakage magnetic field exists, accurate detection of magnetism can be performed. Thus, the electronic compass including the magnetic sensing devices can accurately determine a direction even in an environment in which a leakage magnetic field exists, for example, in a mobile phone.

### BRIEF DESCRIPTION OF THE DRAWINGS

FIG. 1 is a schematic block diagram of a configuration of an electronic compass including a magnetic sensing device according to an embodiment of the present invention.

FIG. 2 illustrates a change in resistance of a magnetoresistive element.

FIG. 3 is a circuit diagram of an electronic compass according to the embodiment of the present invention in stage S1.

FIGS. 4(a) and (b) illustrate peak detection performed by the magnetic sensing device according to the embodiment of the present invention.

FIG. 5 is a flowchart of a process of performing peak detection associated with the magnetoresistive element by the magnetic sensing device according to the present invention.

FIGS. 6(a) and (b) illustrate peak detection performed by the magnetic sensing device according to the embodiment of the present invention.

FIG. 7 is a circuit diagram of the electronic compass according to the embodiment of the present invention in stage S1.

FIG. 8 illustrates a method for detecting an external magnetic field by the magnetic sensing device according to the embodiment of the present invention.

### DESCRIPTION OF THE PREFERRED EMBODIMENTS

The present inventor has taken notice of the following things: a magnetoresistive element that shows a symmetrical change in resistance with respect to a magnetic field is used in a magnetic sensor; and, in such a case, when a peak of the characteristic curve of the magnetoresistive element is broad, it is difficult to perform accurate detection of magnetism in the existence of a leakage magnetic field. Then, the present inventor has found that bias magnetic fields are controlled so that the difference between output voltages obtained by applying the positive and negative magnetic fields becomes substantially zero, thereby performing accurate detection of magnetism. Thus, the present inventor has made the present invention.

The gist of the present invention is as follows: there is provided a magnetic sensing device including a magnetic sensor for detecting magnetism, bias-magnetic-field generating means for applying bias magnetic fields having opposite polarities to each other to the magnetic sensor, detecting means for detecting output voltages that are obtained in response to the bias magnetic fields having the corresponding polarities, calculating means for determining a difference between the output voltages that are obtained in response to the bias magnetic fields having the corresponding polarities, and control means for controlling the bias-magnetic-field generating means so that the difference becomes substantially zero; there is also provided an electronic compass using the magnetic sensing device; and the magnetic sensing device and the electronic compass accurately detect an external magnetic field even in an environment in which a leakage magnetic field exists.

Embodiments of the present invention will be described below in details with reference to the accompanying drawings.

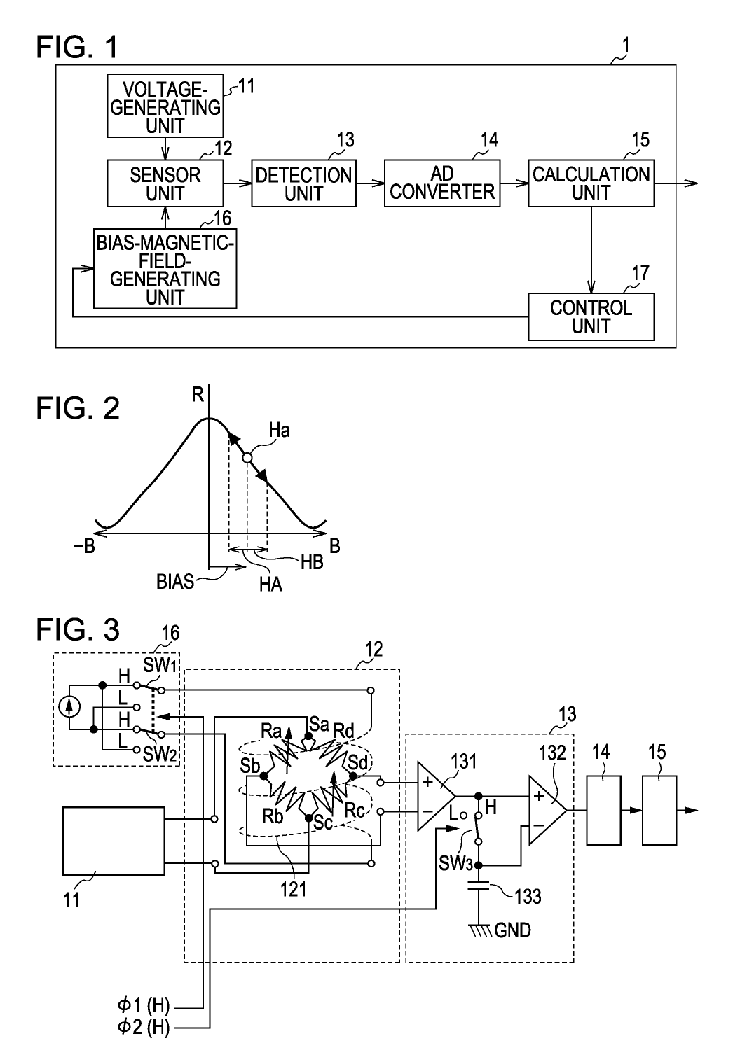

FIG. 1 is a schematic block diagram of a configuration of an electronic compass including a magnetic sensing device according to an embodiment of the present invention.

The magnetic sensing device shown in FIG. 1 includes a sensor unit 12 that outputs a voltage value corresponding to a change in a geomagnetic field, a voltage-generating unit 11 that applies a voltage to the sensor unit 12, a bias-magnetic-field-generating unit 16 that applies a bias magnetic field to the sensor unit 12, a detection unit 13 that detects (amplifies) the voltage value output from the sensor unit 12, an analog-to-digital (AD) converter 14 that converts the voltage value, a calculation unit 15 that determines a direction using digital data obtained by AD conversion, and a control unit 17 that controls the detection unit 13 and the bias-magnetic-field-generating unit 16 on the basis of a calculation result obtained by the calculation unit 15.

The voltage-generating unit 11 applies a voltage to the sensor unit 12. The sensor unit 12 has a configuration defined by three axes, namely, an X axis, a Y axis, and a Z axis. The sensor unit 12 includes a magnetic sensor including a magnetic effect element for detecting a geomagnetic field, and outputs a voltage value corresponding to a change in a geomagnetic field. In this embodiment, the sensor unit 12 is configured as a bridge circuit as shown in FIG. 3. As the magnetic effect element, a magnetoresistive element is used, which shows a change symmetrical with respect to a magnetic field. Examples of the magnetic effect element include a granular in gap (GIG) element and a magneto resistance (MR) element. In this embodiment, a GIG element is used, which can detect a geomagnetic field with a higher sensitivity.

The bias-magnetic-field-generating unit 16 supplies currents that cause bias magnetic fields having opposite polarities to be generated, thereby switching between the bias magnetic fields that are applied to the sensor unit 12. In this embodiment, as shown in FIG. 3, the bias-magnetic-field-generating unit 16 includes switches SW, and SW₂ that are connected to the bridge circuit of the sensor unit 12. Timing at which switching between the bias magnetic fields is performed is controlled by the control unit 17.

The detection unit 13 detects (amplifies) a voltage value output from the sensor unit 12. In this embodiment, as shown in FIG. 3, the detection unit 13 includes an amplifier 131, an amplifier 132 that amplifies the voltage value, a capacitor 133 that accumulates charge in correspondence with the voltage value, and a switch SW₃ that selects whether charge is to be accumulated in the capacitor 133. Timing at which charge is accumulated in correspondence with the voltage value is controlled by the control unit 17.

The AD converter 14 performs AD conversion on an analog voltage value detected by the detection unit 13 to obtain digital data corresponding to the analog voltage value, and outputs the digital data to the calculation unit 15. The AD converter 14 is used with a resolution equivalent to ten bits.

The calculation unit 15 performs calculation among data on the digital data output from the AD converter 14. In other words, the calculation unit 15 determines a first output voltage (for example, V+) for when a bias magnetic field having one polarity is applied, and determines a second output voltage (for example, V−) for when a bias magnetic field having the other polarity is applied. The calculation unit 15 calculates the difference (|(V+)−(V−)|) between the first and second output voltages. Information concerning the calculated difference is output to the control unit 17.

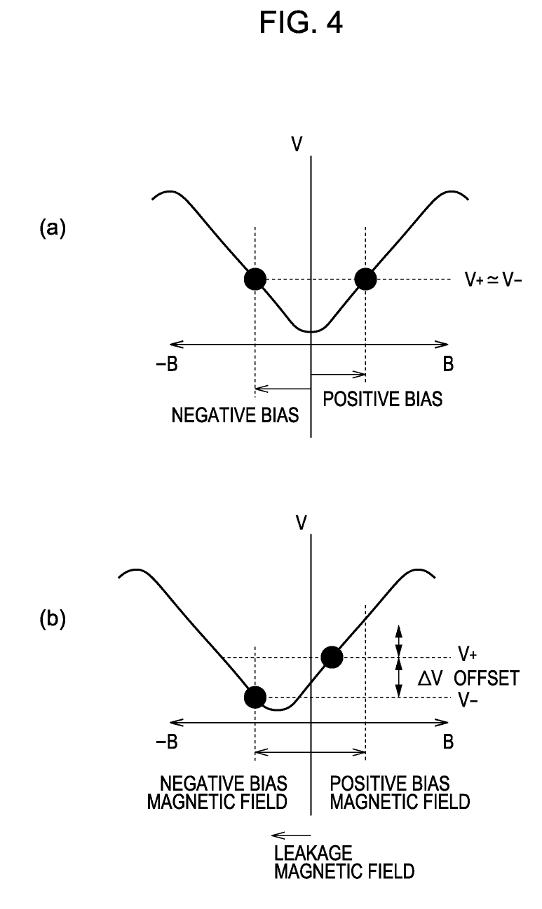

The calculation performed by the calculation unit 15 is described with reference to parts (a) and (b) of FIG. 4. In a case in which no leakage magnetic field acts on the magnetoresistive element, a voltage-versus-magnetic-field characteristic curve of the magnetoresistive element has a peak when a bias magnetic field is zero (at the origin). Accordingly, as shown in part (a) of FIG. 4, the output voltage V+ (the first output voltage), which is obtained by applying a positive bias magnetic field to the sensor unit 12, is substantially the same as the output voltage V− (the second output voltage), which is obtained by applying a negative bias magnetic field whose magnitude is the same as that of the positive bias magnetic field to the sensor unit 12. In other words, the difference (|(V+)−(V−)|) between the first and second output voltages is substantially zero.

In contrast, in a case in which a leakage magnetic field acts on the magnetoresistive element, as shown in part (b) of FIG. 4, the peak of the voltage-versus-magnetic-field characteristic curve of the magnetoresistive element is shifted from the origin (in part (b) of FIG. 4, the peak is shifted to the left side). In this case, when the positive and negative bias magnetic fields whose magnitudes are the same are applied to the sensor unit 12, an offset (ΔV) occurs between output voltages corresponding to the positive and negative bias magnetic fields. In the present invention, an additional bias magnetic field is added to each of the bias magnetic fields, and the bias magnetic fields, each of which includes the additional bias magnetic field, are applied to the sensor unit 12. The additional bias magnetic field is controlled so that the offset ΔV is minimized, i.e., so that the difference (|(V+)−(V−)|) between the first and second output voltages becomes substantially zero. By controlling the additional bias magnetic field, the peak of the voltage-versus-magnetic-field characteristic curve of the magnetoresistive element can be detected.

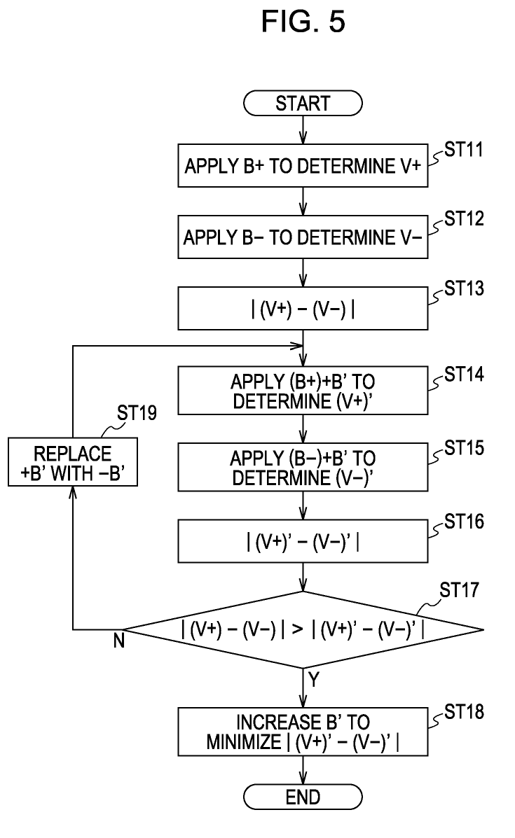

The above-described control is performed by the control unit 17. More specifically, the control is performed in accordance with a flowchart shown in FIG. 5. FIG. 5 is a flowchart of a process of performing peak detection on the magnetoresistive element in the magnetic sensing device according to the present invention. First, a bias magnetic field (B+) having one polarity (the positive polarity in this case) is applied to the sensor unit 12 to determine the first output voltage V+ (ST11). Next, a bias magnetic field (B−) having the other polarity (the negative polarity in this case) is applied to the sensor unit 12 to determine the second output voltage V−(ST12). Then, the difference (|(V+)−(V−)|) between the first output voltage V+ and the second output voltage V− is calculated (ST13).

Next, a correction bias magnetic field, which is obtained by adding an additional bias magnetic field (+B′) to the positive bias magnetic field (B+), is applied to the sensor unit 12 to determine a first output voltage (V+)′ (ST14). Then, a correction bias magnetic field, which is obtained by adding the additional bias magnetic field (+B′) to the negative bias magnetic field (B−), is applied to the sensor unit 12 to determine a second output voltage (V−)′ (ST15). Next, the difference (|(V+)′−(V−)′|) between the first output voltage (V+)′ and the second output voltage (V−)′ is calculated (ST16).

Then, the difference (the offset) in a case in which the bias magnetic fields are applied is compared with the difference (the offset) in a case in which the correction bias magnetic fields are applied (ST17). When the difference (the offset) in a case in which the bias magnetic fields are applied is larger than the difference (the offset) in a case in which the correction bias magnetic fields are applied, the magnitude of the additional bias magnetic field is increased to minimize (|(V+)−(V−)|) (ST18), i.e., to made the difference substantially zero. In contrast, when the difference (the offset) in a case in which the bias magnetic fields are applied is not larger than the difference (the offset) in a case in which the correction bias magnetic fields are applied, the polarity of the additional bias magnetic field is changed, and the process onward from ST14 is performed (ST19). In this manner, the additional bias magnetic field can be obtained, which corresponds to the shift of the peak of the magnetoresistance characteristics that is caused by the leakage magnetic field. Accordingly, the additional bias magnetic field is used as a correction value, whereby the shift of the peak of the magnetoresistance characteristics that is caused by the leakage magnetic field can be corrected.

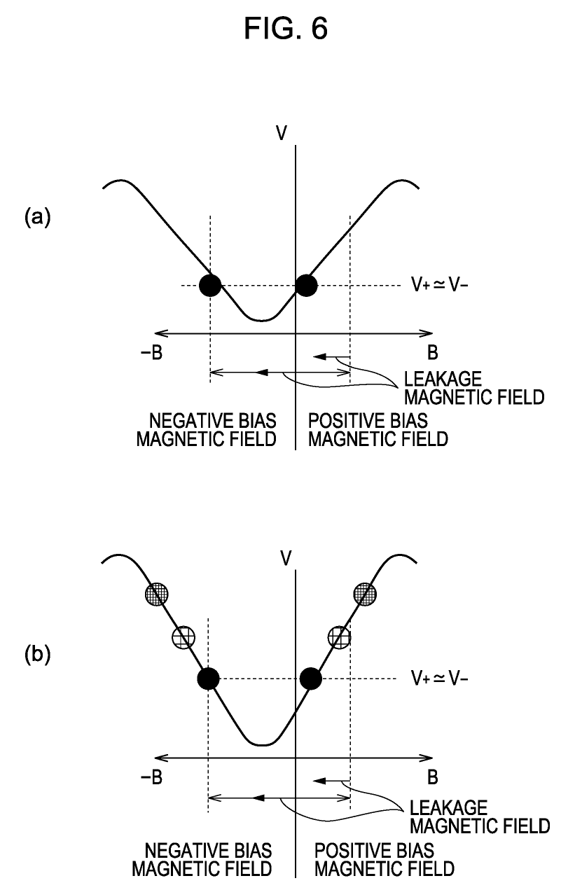

By performing the above-described process, as shown in part (a) of FIG. 6, the offset ΔV is minimized, i.e., the difference (|(V+)−(V−)|) between the first and second output voltages is made substantially zero. Thus, even when a leakage magnetic field acts on the magnetoresistive element, the peak of the voltage-versus-magnetic-field characteristic curve of the magnetoresistive element can be detected. As a result, even in an environment in which a leakage magnetic field exists, accurate detection of magnetism can be performed. Accordingly, an electronic compass including the magnetic sensing device can accurately determine a direction even in an environment in which a leakage magnetic field exists, for example, in a mobile phone. Additionally, peak detection is performed by making the difference between the output voltages obtained in a case in which the positive and negative bias magnetic fields are applied substantially zero. Thus, even when a central portion (a peak) of the magnetoresistance characteristics of a magnetoresistive element to be used has broad characteristics or hysteresis characteristics, accurate detection of magnetism can be performed.

In a case in which the process is performed as described above, pairs of bias magnetic fields (plotted using points filled with black color, a grid pattern, and a checkered pattern shown in part (b) of FIG. 6) may be applied to the sensor unit 12. The magnitudes of the pairs of bias magnetic fields are different from one another, and each of the pairs of bias magnetic fields have opposite polarities. Then, the above-described control for each of the pairs of bias magnetic fields, i.e., the control in which the difference between the output voltages corresponding to the pair of bias magnetic fields is made substantially zero, may be performed. By using the pairs of bias magnetic fields as described above, a peak of magnetoresistance characteristics can be detected with a higher accuracy. In the above-described case in which the pairs of bias magnetic fields are applied, when peak detection is performed, an additional bias magnetic field is obtained for each of the pairs of bias magnetic fields. In this case, statistical processing, such as average processing or distributed processing, is performed on the values of additional bias magnetic fields for the pairs of bias magnetic fields in order to determine a preferable additional bias magnetic field.

The control unit 17 supplies control signals φ1 and φ2 to the detection unit 13 and the bias-magnetic-field-generating unit 16 in order to control each processing unit. Additionally, the control unit 17 also has a function of controlling data communication between the electronic compass and an external unit. In this case, in order to reduce the overall power consumption, the control unit 17 performs control of turning on/off each processing unit.

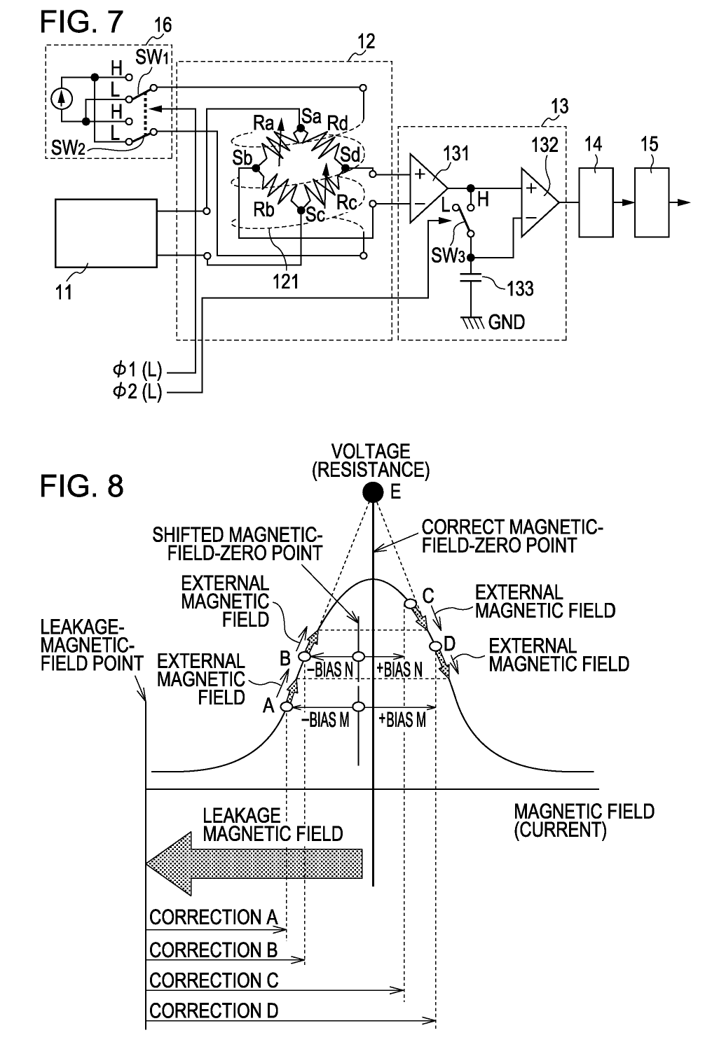

Next, an operation of an electronic compass according to the present invention is described with reference to circuit diagrams shown in FIGS. 3 and 7. FIGS. 3 and 7 each are a circuit diagram of an electronic compass according to an embodiment of the present invention. In FIGS. 3 and 7, for simplicity of description, control signals that are input are illustrated without the control unit being illustrated.

First, the magnetoresistive element used in the sensor unit 12 exhibits a magnetoresistance effect that is symmetrical with respect to a magnetic field is shown in FIG. 2. In other words, when no magnetic field exists, the resistance of the magnetoresistive element becomes maximum. When a magnetic field is applied in either a positive direction or a negative direction, the resistance decreases. When a positive bias magnetic field is applied to the magnetoresistive element, as shown in FIG. 2, the resistance changes about Ha due to the bias magnetic field. When another magnetic field provided from the outside, such as a geomagnetic field, acts on the magnetoresistive element in this state, the value of the resistance changes. When the direction of the magnetic field is the same as that of the bias magnetic field, the value of the resistance decreases. When the direction of the magnetic field is different from that of the bias magnetic field, the value of the resistance increases.

In this embodiment, the sensor unit 12 is configured as the bridge circuit. In the bridge circuit shown in FIG. 3, Ra and Rc are magnetoresistive elements. Rb and Rd are fixed resistances. A voltage is applied between one pair of terminals of the bridge circuit, namely, terminals Sa and Sc, voltages that are obtained by dividing the applied voltage on the basis of corresponding resistances are output from the other pair of terminals, namely, terminals Sb and Sd. The resistances of the Ra and Rc, which configures the bridge circuit, are changed due to magnetism, and voltages are output in response to the magnetism.

As shown in FIG. 3, the bias-magnetic-field-generating unit 16 switches, using the control signal φ1 supplied from the control unit 17, a direction of a current that flows through the coil 121 mounted in the sensor unit 12, thereby applying bias magnetic fields having opposite polarities to the sensor unit 12. When the level of the control signal φ1 is high (an H signal), the current flows in a clockwise direction when viewed from the top side using the switches SW₁ and SW₂, and, in the sensor unit 12, a bias magnetic field is generated in a direction HA shown in FIG. 2. When the level of the control signal φ1 is low (a L signal), the current flows in a direction opposite to the above-mentioned direction using the switches SW₁ and SW₂, and, in the sensor unit 12, a bias magnetic field is generated in a direction HB shown in FIG. 2.

In the detection unit 13, the amplifier 131 is connected to the terminals Sb and Sd of the bridge circuit, and obtains the output of the sensor unit 12. Charge is accumulated in the capacitor 133 via the switch SW₃ in correspondence with the obtained voltage. Additionally, the obtained voltage is applied to an input terminal of the amplifier 132. The switch SW₃ is controlled by the control signal φ2 supplied from the control unit 17. When the level of the control signal φ2 is high (an H signal), the control signal φ2 causes the output of the amplifier 131 to have a connection with the capacitor 133. When the level of the control signal φ2 is low (a Low signal), the control signal φ2 causes the output of the amplifier 131 to be released from the connection with the capacitor 133. The amplifier 132 operates so as to amplify the difference between the voltage value of the capacitor 133 and a voltage value that is obtained as the output of the amplifier 131. By this operation of the amplifier 132, the difference between the voltage values obtained in a case in which the direction of the bias magnetic field applied to the sensor unit 12 is switched is amplified and output.

In this configuration, when the bias magnetic field (B+) having one polarity (the positive polarity in this case) is applied to the sensor unit 12 in order to determine the first output voltage V+, as shown in FIG. 3, each of the switches SW₁ and SW₂ is switched to H by the control signal φ1 supplied from the control unit 17. Additionally, in order to maintain the first output voltage V+, the switch SW₃ is switched to H by the control signal φ2 supplied from the control unit 17. In contrast, when the bias magnetic field (B−) having the other polarity (the negative polarity in this case) is applied to the sensor unit 12 in order to determine the second output voltage V−, as shown in FIG. 7, each of the switches SW₁ and SW₂ is switched to L by the control signal φ1 supplied from the control unit 17. Additionally, in order to compare the second output voltage V− with the first output voltage V+ in the amplifier 132, the switch SW₃ is switched to L by the control signal φ2 supplied from the control unit 17. In this manner, the difference (|(V+)−(V−)|) between the first output voltage V+ and the second output voltage V− is calculated.

Next, when a direction is to be determined by the electronic compass having the configuration given above, the bias magnetic fields having polarities opposite to each other are applied, thereby utilizing a change in resistance of the magnetoresistive element to determine a change in resistance value as a voltage value. Then, a current is added in a certain direction so that the applied bias magnetic fields are cancelled out to determine a current value corresponding to an external magnetic field (a geomagnetic field). The intensity (voltage) of the external magnetic field is determined using the current value. In this case, adding a current in a certain direction so that the external magnetic field is cancelled out is equivalent to moving the resistance to the position of a peak shown in FIG. 2. Accordingly, as described in this embodiment, when the peak is detected, a current can be accurately added in a certain direction so that the external magnetic field is cancelled out, whereby the external magnetic field can be accurately determined. Because the sensor unit 12 has a configuration defined by three axes that are the X axis, the Y axis, and the Z axis, each of an external magnetic field for the X axis, an external magnetic field for the Y axis, and an external magnetic field for the Z axis is determined by the foregoing process. A direction is determined using the external magnetic fields. More specifically, the arctangent of a ratio of a voltage corresponding to the external magnetic field for the X axis to a voltage corresponding to the external magnetic field for the Y axis is determined to calculate the direction. The voltage corresponding to the external magnetic field for the Z axis is used in calculation that causes a state in which the electronic compass is inclined to be corrected. For example, the electronic compass according to the present invention is mounted in a mobile phone or the like, there is probability that the mobile phone is used in a state in which it is inclined. In such a case, for example, correction calculation is performed using the external magnetic field for the Z axis to calculate a direction.

Next, an embodiment is described, to which a method for detecting an external magnetic field by the magnetic sensing device according to the present invention is applied. FIG. 8 illustrates the method for detecting an external magnetic field by the magnetic sensing device according to the embodiment of the present invention.

In this method, when the bias-magnetic-field-generating unit 16 applies a first pair of bias magnetic fields to the sensor unit 12, a first pair of correction magnetic fields is obtained in a case in which the difference between output voltages is made substantially zero. When the bias-magnetic-field-generating unit 16 applies a second pair of bias magnetic fields, whose magnitude is different from that of the first pair of bias magnetic fields, to the sensor unit 12, a second pair of correction magnetic fields is obtained in a case in which the difference between output voltages is made substantially zero. An external magnetic field is determined using the first pair of correction magnetic fields and the second pair of correction magnetic fields. The calculation is performed by the calculation unit 15.

As is clear from FIG. 8, an external magnetic field (a geomagnetic field) acts on the magnetic sensor. Additionally, a comparatively large leakage magnetic field acts on the magnetic sensor. Accordingly, in this state, a magnetic-field-zero point (a correct magnetic-field-zero point) of the magnetoresistive element is shifted to a leakage-magnetic-field-point side (a shifted magnetic-field-zero point). For this reason, even if detection of the external magnetic field is performed in this state, it is difficult to accurately detect the external magnetic field.

Accordingly, in this detection method, an approximate line is determined using the values of correction magnetic fields having one polarity, each of which is included in a corresponding one of the first and second pairs of correction magnetic fields. Another approximate line is determined using the values of correction magnetic fields having the other polarity, each of which is included in a corresponding one of the first and second pairs of correction magnetic fields. The magnetic-field-zero point is determined using the approximate lines, and the external magnetic field is determined using the magnetic-field-zero point and the first or second pair of correction magnetic fields.

First, each bias magnetic field included in a pair of bias magnetic fields (a -bias M and a +bias M) having a certain magnitude is applied to the sensor unit 12. As described above, the process is performed so as to made the difference between output voltages substantially zero. In this manner, a pair of correction magnetic fields (a correction A and a correction D) is obtained. As is clear from FIG. 8, a voltage A in the case of the correction A is not equivalent to a voltage D in the case of the correction D. However, a voltage in the case of the correction A+ the external magnetic field is substantially equivalent to a voltage in the case of the correction D+the external magnetic field.

Each bias magnetic field included in a pair of bias magnetic fields (a −bias N and a +bias N) having a magnitude different from the above magnitude is applied to the sensor unit 12. As described above, the process is performed so as to made the difference between output voltages substantially zero. In this manner, a pair of correction magnetic fields (a correction B and a correction C) is obtained. As is clear from FIG. 8, a voltage B in the case of the correction B is not equivalent to a voltage D in the case of the correction D. However, a voltage in the case of the correction B+ the external magnetic field is substantially equivalent to a voltage in the case of the correction D+ the external magnetic field.

In this manner, the voltages A to D corresponding to the correction magnetic fields A to D are determined. Next, the correct magnetic-field-zero point is determined using the two voltages A and B, which correspond to the biases having one polarity, and the voltages C and D, which correspond to the biases having the other polarity. In other words, the magnetic-field-zero point is positioned at an intersection of the approximate line running from the voltage A to the voltage B and the approximate line running from the voltage C to the voltage D.

Because the relationship between the external magnetic field and the magnetic-field-zero point is obtained as follows, the external magnetic field can be determined using the following equation:

(correction magnetic field A+correction magnetic field B)/2=magnetic-field-zero point−external magnetic field

When this equation is modified,

external magnetic field=magnetic-field-zero point−(correction magnetic field A+correction magnetic field B)/2

In this manner, by using the detection method, even when a comparatively large leakage magnetic field exists, the external magnetic field can be accurately detected. Additionally, the correction magnetic fields are sifted by the external magnetic field, whereby an appropriate offset value can be determined.

The magnetic sensing device according to the present invention includes a magnetic sensor for detecting magnetism, bias-magnetic-field generating means for applying bias magnetic fields having opposite polarities to the magnetic sensor, detecting means for detecting output voltages that are obtained in response to the bias magnetic fields having the corresponding polarities, calculating means for determining a difference between the output voltages that are obtained in response to the bias magnetic fields having the corresponding polarities, and control means for controlling the bias-magnetic-field generating means so that the difference becomes substantially zero. Therefore, the magnetic sensing device, which can accurately detect an external magnetic field even in an environment in which a leakage magnetic field exists, and the electronic compass using the magnetic sensing device can be provided.

The configurations that are described in the embodiments according to the present invention are not limited thereto. Various modifications may be appropriately made without departing from the scope of the present invention.

1. A magnetic sensing device comprising:
a magnetic sensor for detecting magnetism;
bias-magnetic-field generating means for applying bias magnetic fields having opposite polarities to each other to the magnetic sensor;
detecting means for detecting output voltages that are obtained in response to the bias magnetic fields having the corresponding polarities;
calculating means for determining a difference between the output voltages that are obtained in response to the bias magnetic fields having the corresponding polarities; and
control means for controlling the bias-magnetic-field generating means so that the difference becomes substantially zero.

2. The magnetic sensing device according to claim 1, wherein the bias-magnetic-field generating means applies pairs of bias magnetic fields to the magnetic sensor, the magnitudes of the pairs of bias magnetic fields being different from one another, each of the pairs of bias magnetic fields having opposite polarities, and the control means controls the bias-magnetic-field generating means so that a difference between output voltages corresponding to each of the pairs of bias magnetic fields becomes substantially zero.

3. The magnetic sensing device according to claim 1, wherein the calculating means determines an external magnetic field acting on the magnetic sensor using a first pair of correction magnetic fields and a second pair of correction magnetic fields, the first pair of correction magnetic fields being obtained in a case in which the difference between the output voltages becomes substantially zero when the bias-magnetic-field generating means applies a first pair of bias magnetic fields to the magnetic sensor, the second pair of correction magnetic fields being obtained in a case in which the difference between the output voltages becomes substantially zero when the bias-magnetic-field generating means applies a second pair of bias magnetic fields to the magnetic sensor, the magnitude of the second pair of bias magnetic fields being different from that of the first pair of bias magnetic fields.

4. The magnetic sensing device according to claim 2, wherein the calculating means determines an external magnetic field acting on the magnetic sensor using a first pair of correction magnetic fields and a second pair of correction magnetic fields, the first pair of correction magnetic fields being obtained in a case in which the difference between the output voltages becomes substantially zero when the bias-magnetic-field generating means applies a first pair of bias magnetic fields to the magnetic sensor, the second pair of correction magnetic fields being obtained in a case in which the difference between the output voltages becomes substantially zero when the bias-magnetic-field generating means applies a second pair of bias magnetic fields to the magnetic sensor, the magnitude of the second pair of bias magnetic fields being different from that of the first pair of bias magnetic fields.

5. The magnetic sensing device according to claim 3, wherein an approximate line is determined using values of correction magnetic fields having one polarity, each of the correction magnetic fields being included in a corresponding one of the first and second pairs of correction magnetic fields, an approximate line is determined using values of correction magnetic fields having the other polarity, each of the correction magnetic fields being included in a corresponding one of the first and second pairs of correction magnetic fields, a magnetic-field-zero point is determined using the approximate lines, and the external magnetic field is determined using the magnetic-field-zero point and the first or second pair of correction magnetic fields.

6. The magnetic sensing device according to claim 4, wherein an approximate line is determined using values of correction magnetic fields having one polarity, each of the correction magnetic fields being included in a corresponding one of the first and second pairs of correction magnetic fields, an approximate line is determined using values of correction magnetic fields having the other polarity, each of the correction magnetic fields being included in a corresponding one of the first and second pairs of correction magnetic fields, a magnetic-field-zero point is determined using the approximate lines, and the external magnetic field is determined using the magnetic-field-zero point and the first or second pair of correction magnetic fields.

7. The magnetic sensing device according to claim 1, wherein the magnetic sensor includes a magnetoresistive element that shows a symmetrical change in resistance with respect to a magnetic field.

8. The magnetic sensing device according to claim 7, wherein the magnetoresistive element is a GIG element or an MR element.

9. The magnetic sensing device according to claim 1, wherein the magnetic sensor is configured as a bridge circuit.

10. An electronic compass comprising:
a plurality of the magnetic sensing devices according to claim 1; and
direction-calculating means for determining a direction using voltage differences, each of which is obtained by a corresponding one of the magnetic sensing devices.
